(19) United States
(12) Patent Application Publication
(10) Pub. No.: US 2024/0243542 A1
(43) Pub. Date: Jul. 18, 2024

(54) OPTICAL RESONATOR AND LASER DEVICE

(71) Applicant: SONY GROUP CORPORATION, TOKYO (JP)

(72) Inventors: KENJI TANAKA, TOKYO (JP); GEN YONEZAWA, TOKYO (JP); MASANAO KAMATA, TOKYO (JP); HIROSHI TOBITA, TOKYO (JP); GO HIRANO, TOKYO (JP)

(21) Appl. No.: 18/558,754

(22) PCT Filed: Feb. 15, 2022
(86) PCT No.: PCT/JP2022/005847

§ 371 Date: Nov. 3, 2023

(30) Foreign Application Priority Data
May 26, 2021 (JP) 2021-088663

(51) Int. Cl. H01S 3/1123; H01S 3/08

(52) U.S. Cl. CPC H01S 3/1123; H01S 3/08009; H01S 3/08054

(57) ABSTRACT

An optical resonator having a short pulse width, a low manufacturing cost, and a high degree of freedom in design is provided. An optical resonator according to one aspect of the present disclosure includes a pair of reflection members, a laser medium that is disposed between the pair of reflection members and is excited by specific excitation light to emit emission light, and a polarization control unit that is disposed between the pair of reflection members and controls polarization of the emission light, in which the polarization control unit has a microstructure on a surface so as to have different transmittances for polarized light beams orthogonal to each other out of zeroth-order diffracted light of the emission light.

### TECHNICAL FIELD

The present disclosure relates to an optical resonator and a laser device.

### BACKGROUND ART

A laser device is disclosed in which a polarizer is disposed between a pair of mirrors constituting an optical resonator in order to control a polarization direction of laser beam. However, since the polarizer is disposed to be inclined between the mirrors, a space for disposing the polarizer is necessary. Therefore, the resonator becomes long, and it is difficult to make the laser device compact. Furthermore, when the resonator becomes long, the pulse width of the laser beam becomes long, and the peak power of the laser beam decreases.

Furthermore, a laser device using a photonic crystal as a polarizing element is also disclosed. However, in a case where the photonic crystal is used, a special process is required in the manufacturing process of the laser device, and the manufacturing cost increases. Furthermore, the position of the reflection mirror and the material used are limited, and the degree of freedom in design is reduced.

### CITATION LIST

### Patent Document

Patent Document 1: Japanese Patent Application Laid-Open No. 2017-183505
Patent Document 2: Japanese Patent Application Laid-Open No. 2019-176119
Patent Document 3: WO 2018/221083

### SUMMARY OF THE INVENTION

### Problems to be Solved by the Invention

An optical resonator having a short pulse width, a low manufacturing cost, and a high degree of freedom in design will be provided.

### Solutions to Problems

An optical resonator according to one aspect of the present disclosure includes a pair of reflection members, a laser medium that is disposed between the pair of reflection members and is excited by specific excitation light to emit emission light, and a polarization control unit that is disposed between the pair of reflection members and controls polarization of the emission light, in which the polarization control unit has a microstructure on a surface so as to have different transmittances for polarized light beams orthogonal to each other out of zeroth-order diffracted light of the emission light.

The microstructure is a grating structure.

The microstructure is an uneven structure having a period equal to or less than a wavelength of the emission light.

The microstructure is an uneven structure having a depth equal to or less than ¼ of a wavelength of the emission light.

A surface layer provided on a surface of the microstructure is further included.

In the polarization control unit, a transparent material is used for the emission light.

The polarization control unit is joined to the laser medium or another member and constitutes an integrated optical resonator.

The pair of reflection members, the polarization control unit, and the laser medium constitute an integrated optical resonator.

A saturable absorber disposed on an optical axis of the optical resonator is further included between the pair of reflection members.

A transparent member including a material transparent to emission light or excitation light, the transparent member being disposed on an optical axis of the optical resonator between the pair of reflection members or outside the reflection member on an incident side of the excitation light is further included.

Any one of a dielectric (for example, Al₂O₃, SiO₂, Ta₂O₅, or HfO₂) and a semiconductor (for example, GaN, InN, or AlN) is used for the polarization control unit, and for example, quartz (SiO₂) is used for the surface layer.

The microstructure is a photonic crystal or a meta-surface structure.

An optical resonator according to one aspect of the present disclosure includes a pair of reflection members, a laser medium that is disposed between the pair of reflection members and is excited by specific excitation light to emit emission light, and a saturable absorber disposed on an optical axis of the optical resonator between the pair of reflection members, in which any one of the saturable absorber, the laser medium, or the reflection member has a microstructure on a surface so as to have different transmittances for polarized light beams orthogonal to each other out of zeroth-order diffracted light of the emission light.

The microstructure is a grating structure.

The microstructure is an uneven structure having a period equal to or less than a wavelength of the emission light.

The microstructure is an uneven structure having a depth equal to or less than ¼ of a wavelength of the emission light.

A surface layer provided on a surface of the microstructure is further included.

The pair of reflection members, the polarization control unit, and the laser medium constitute an integrated optical resonator.

A transparent member including a material transparent to emission light or excitation light, the transparent member being disposed on an optical axis of the optical resonator between the pair of reflection members or outside the reflection member on an incident side of the excitation light is further included.

The microstructure is a photonic crystal or a meta-surface structure.

Any one of the optical resonators described above and a light source that irradiates the laser medium with the excitation light are included.

In the laser device according to one aspect of the present disclosure, any of the optical resonators described above and the light source are integrally formed.

A laser device according to one aspect of the present disclosure includes any one of the optical resonators described above and an excitation light resonator that oscillates the excitation light.

### BRIEF DESCRIPTION OF DRAWINGS

FIG. 1 is a schematic diagram illustrating a configuration example of a laser device according to a first embodiment.

FIG. 2 is a graph illustrating polarization characteristics of a polarization control unit.

FIG. 3 is a schematic diagram illustrating a configuration example of an optical resonator according to a second embodiment.

FIG. 4 is a schematic diagram illustrating a configuration example of an optical resonator according to a modification of the second embodiment.

FIG. 5 is a schematic diagram illustrating a configuration example of an optical resonator according to a third embodiment.

FIG. 6 is a schematic diagram illustrating a configuration example of an optical resonator according to a fourth embodiment.

FIG. 7 is a schematic diagram illustrating a configuration example of an optical resonator according to a fifth embodiment.

FIG. 8 is a schematic diagram illustrating a configuration example of an optical resonator according to a sixth embodiment.

FIG. 9 is a schematic diagram illustrating a configuration example of an optical resonator according to a seventh embodiment.

FIG. 10A is a schematic diagram illustrating a configuration example of an optical resonator according to an eighth embodiment.

FIG. 10B is a schematic diagram illustrating a configuration example of an optical resonator according to the eighth embodiment.

FIG. 11 is a schematic diagram illustrating a configuration example of a polarization control unit according to a ninth embodiment.

FIG. 12 is a schematic diagram illustrating a configuration example of a laser device according to a tenth embodiment.

FIG. 13 is a diagram illustrating a configuration example of a laser device according to an eleventh embodiment.

FIG. 14 is a block diagram illustrating an application example in which the laser device according to the present embodiment is applied to a laser processing device.

### MODE FOR CARRYING OUT THE INVENTION

Hereinafter, specific embodiments to which the present technology is applied will be described in detail with reference to the drawings. The drawings are schematic or conceptual, and the ratio of each part and the like are not necessarily the same as actual ones. In the description and the drawings, elements similar to those described above with respect to previously described drawings are denoted by the same reference numerals, and detailed descriptions thereof are appropriately omitted.

### First Embodiment

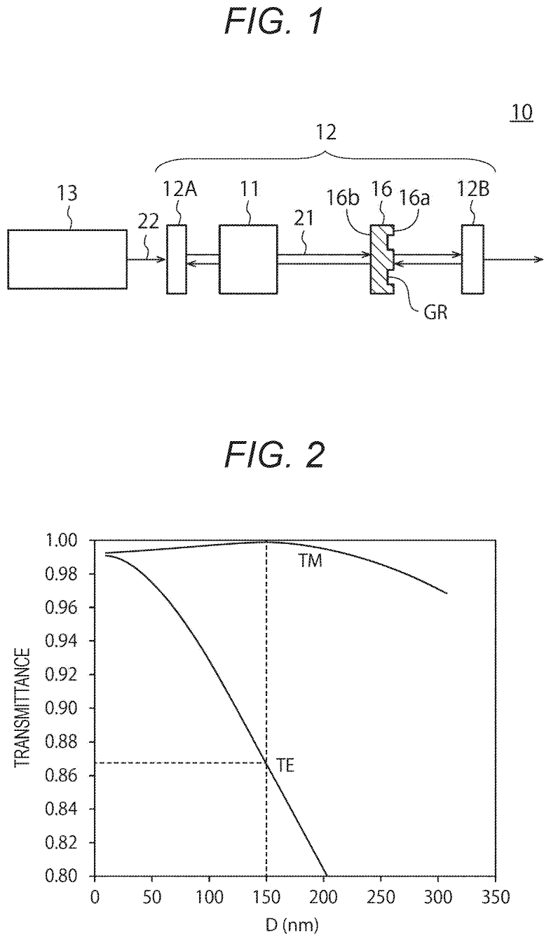

FIG. 1 is a schematic diagram illustrating a configuration example of a laser device according to a first embodiment. A laser device 10 includes an optical resonator 12 and a light source 13.

The light source 13 outputs excitation light 22 for exciting a laser medium 11. The light source 13 is disposed outside a pair of reflection members 12A and 12B, and emits the excitation light 22 having a wavelength around 940 nm for exciting the laser medium 11 (for example, Yb:YAG). The light source 13 includes, for example, a semiconductor laser element that emits the excitation light 22 and an optical system (lens and the like) that causes the excitation light 22 to enter the laser medium 11 via the reflection member 12A.

Note that the light source 13 may be other than a semiconductor laser element as long as it can emit the excitation light 22 that can excite the laser medium 11. In addition, the material used for the light source 13 may be a crystalline material or an amorphous material. In addition, the light source 13 may not include an optical system such as a lens as long as the excitation light 22 can be incident on the laser medium 11.

The optical resonator 12 includes the pair of reflection members (mirrors) 12A and 12B, the laser medium 11, and a polarization control unit 16. The optical resonator 12 is, for example, a solid-state laser oscillator, but is not limited thereto. The reflection members 12A and 12B, the laser medium 11, and the polarization control unit 16 are arranged along optical axes of the excitation light 22 and the emission light 21.

Out of the pair of reflection members 12A and 12B, the reflection member 12A provided on the light source 13 side is, for example, a mirror that transmits the excitation light 22 having a wavelength of about 940 nm emitted from the light source 13 and reflects the emission light 21 of about 1030 nm emitted from the laser medium 11 with a predetermined reflectance. The use of a mirror for the reflection member 12A is merely an example, and can be changed as appropriate. For example, an element including a dielectric multilayer film may be used for the reflection member 12A. In a case where a dielectric multilayer film is used, the thickness of the layer is generally ¼ of the laser oscillation wavelength, the total number is several layers to several hundred layers, and SiO₂, SiN, or the like can be used as the material. Note that the above is an example, and examples are not limited thereto.

The solid-state laser medium 11 contains, for example, ytterbium (Yb)-doped yttrium aluminum garnet (YAG) crystal Yb:YAG. In this case, a first wavelength λ1 of a first resonator 15 is 940 nm, and a second wavelength λ2 of a second resonator 12 is 1030 nm.

The solid-state laser medium 11 is not limited to Yb:YAG, and for example, at least any material of Nd:YAG, Nd:YVO4, Nd:YLF, Nd:glass, Yb:YAG, Yb:YLF, Yb:FAP, Yb:SFAP, Yb:YVO, Yb:glass, Yb:KYW, Yb:BCBF, Yb:YCOB, Yb:GdCOB, and Yb:YAB can be used as the solid-state laser medium 11.

Furthermore, the solid-state laser medium 11 may be a four-level system solid-state laser medium 11 or a three-level system solid-state laser medium 11. However, since an appropriate excitation wavelength (first wavelength λ1) varies depending on each crystal, it is necessary to select the semiconductor material of the light emitting element 1 according to the material of the solid-state laser medium 11. In addition, a reflection layer (for example, a dielectric multilayer film) that reflects the excitation light may be provided on a surface of the solid-state laser medium 11 on the laser output side (reflection member 12B side).

In the following description, the light emitted by the laser medium 11 is referred to as emission light 21.

The polarization control unit 16 is disposed on the optical axis of the optical resonator 12 between the reflection member 12A and the reflection member 12B and acts on the emission light 21. For the polarization control unit 16, for example, a dielectric (for example, Al₂O₃, SiO₂, Ta₂O₅, or HfO₂), a semiconductor (for example, GaN, InN, or AlN), or the like is used, and a material transparent to the emission light 21 is used. The thickness of the polarization control unit 16 is, for example, about 500 μm. The polarization control unit 16 has a first surface 16a and a second surface 16b opposite to the first surface 16a. A grating structure GR as a microstructure is formed on the first surface 16a of the polarization control unit 16. The grating structure GR may be, for example, an uneven structure having a period equal to or less than the wavelength of the emission light 21 and having a depth equal to or less than ¼ of the wavelength of the emission light 21. The grating structure GR is, for example, a one-dimensional surface relief grating structure using zeroth-order diffracted light (transmitted light). That is, the pattern of the grating structure GR is what is called a line-and-space pattern. Thus, the polarization control unit 16 has different transmittances for polarized light beams (transverse magnetic wave (TM) and transverse electric wave (TE)) orthogonal to each other out of the zeroth-order diffracted light (transmitted light) of the emission light 21. Furthermore, the polarization of the emission light 21 is controlled in one direction by the polarization control unit 16 instead of random polarization, and thus it is possible to improve the characteristics of the optical resonator 12 such as stabilization of oscillation output and improvement of wavelength conversion efficiency.

FIG. 2 is a graph illustrating polarization characteristics of the polarization control unit 16. The vertical axis represents the transmittance of the polarization control unit 16, and the horizontal axis represents the depth (height) of the unevenness of the grating structure GR. According to the graph of FIG. 2, when the depth of the unevenness of the grating structure GR is set to 150 nm, the polarization control unit 16 can suppress the TE polarized light beam to about 86% while transmitting about 100% of the TM polarized light beam. Moreover, the polarization characteristic of the polarization control unit 16 can be controlled by changing the depth and period of the unevenness of the grating structure GR, the refractive index of the polarization control unit 16, and the like.

By providing such a polarization control unit 16 capable of controlling polarization between the pair of reflection members 12A and 12B, it is possible to control the polarization of the emission light 21.

As described above, according to the present embodiment, the laser medium 11 and the polarization control unit 16 are provided between the pair of reflection members 12A and 12B constituting the optical resonator 12. With the surface relief grating structure using the zeroth-order diffracted light, the polarization control unit 16 has different transmittances in the polarized light beams (TM and TE) orthogonal to each other. Thus, the polarization control unit 16 has a high transmittance in the TM polarized light beam as main polarization and has a small loss in laser oscillation. On the other hand, the polarization control unit 16 has a relatively low transmittance in the TE polarized light beam. Therefore, the polarization control unit 16 has high anisotropy in the orthogonal polarized light beams (TM and TE), and can cause the TM polarized light beam to pass and oscillate selectively. As a result, the optical resonator 12 can stably and efficiently generate a laser beam by the TM polarized light beam as a main polarized light beam. Furthermore, the polarization control unit 16 does not need to be inserted obliquely to the optical axis of the optical resonator 12, and the optical resonator 12 can be made compact.

Note that, in the first embodiment, a device or an optical element that enables pulsed light emission, for example, a saturable absorber is not provided. Therefore, the laser device 10 according to the first embodiment is a continuous wave (CW) laser that continuously oscillates a laser beam.

Furthermore, at least one of the pair of reflection members 12A and 12B may be a polarizing element having a polarization selecting function. For example, out of the pair of reflection members 12A and 12B, the reflection member 12A provided on the light source 13 side may be a polarizing element, the reflection member 12B disposed so as to face the reflection member 12A may be a polarizing element, or both the reflection members 12A and 12B may be polarizing elements. For example, the reflection member 12B installed so as to face the reflection member 12A is a polarizing element in which the transmittance and the reflectance of the emission light 21 are different depending on the polarization direction. Note that the member used as the polarizing element according to the present embodiment is not particularly limited. A case where linearly polarized light is achieved by the polarizing element according to the present embodiment will be mainly assumed and described, but it is not limited thereto, and various polarization states such as circularly polarized light, elliptically polarized light, and radially polarized light may be achieved by the polarizing element according to the present embodiment.

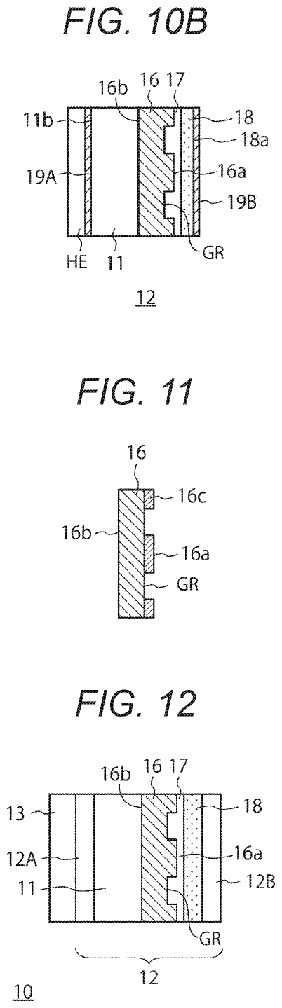

Moreover, a transparent member (see HE in FIG. 10B) may be provided outside the reflection member 19A on the excitation light incident side of the pair of reflection members 12A and 12B. As the transparent member, for example, a sapphire (Al₂O₃) substrate is used. The transparent member (HE) illustrated in FIG. 10B has a heat exhaust function to exhaust heat of the laser medium 11. This transparent member can be applied to any of the following embodiments and modifications.

Note that the transparent member HE may be provided at any position between optical elements between the pair of reflection members 12A and 12B. In this case, the transparent member HE has a function of a spacer that adjusts the length of the optical resonator 12 in an optical axis direction. Furthermore, in a case where the transparent member HE is located adjacent to the laser medium 11, the transparent member HE has both a heat exhaust function to exhaust heat of the laser medium 11 and a function of a spacer.

### Second Embodiment

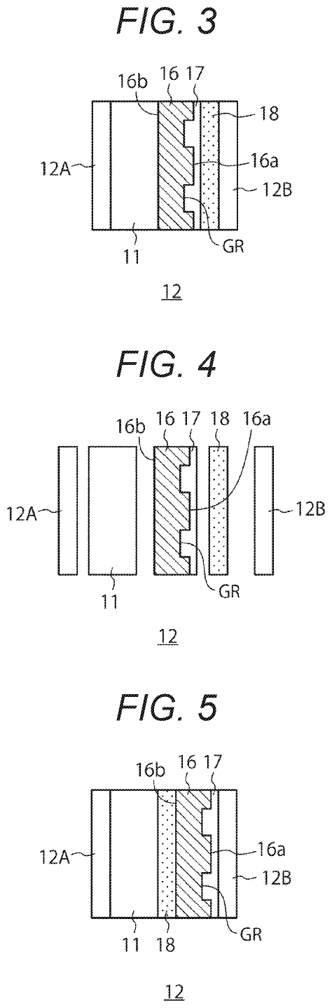

FIG. 3 is a schematic diagram illustrating a configuration example of an optical resonator 12 according to a second embodiment. The optical resonator 12 according to the second embodiment further includes a surface layer 17 and a saturable absorber 18.

The surface layer 17 is provided so as to cover the grating structure GR on the first surface 16a of the polarization control unit 16. The surface layer 17 is provided to fill and planarize the grating structure GR and enable the polarization control unit 16 to be joined to another optical element. For example, quartz (SiO₂) is used for the surface layer 17. The thickness of the surface layer 17 is, for example, equal to or less than 10 μm. The average arithmetic roughness (roughness) of the surface of the surface layer 17 is preferably less than 1 nm, and more preferably less than 0.5 nm.

The saturable absorber 18 is disposed on the optical axis of the optical resonator 12 between the pair of reflection members 12A and 12B. The saturable absorber 18 is provided between the surface layer 17 on the first surface 16a of the polarization control unit 16 and the reflection member 12B. As the saturable absorber 18, for example, Cr:YAG or V:YAG is used. For example, chemical mechanical polishing (CMP) is used to implement the surface layer having such arithmetic average roughness.

The saturable absorber 18 is, for example, a member formed by Cr:YAG and having a property that a light absorption rate decreases due to saturation of light absorption. The saturable absorber 18 functions as passive Q-switching in the laser device 10. In this case, the laser device 10 is a passive Q-switched pulsed laser device.

For example, when the emission light 21 from the laser medium 11 is incident, the saturable absorber 18 absorbs the emission light 21, and the transmittance of the saturable absorber 18 increases along with the absorption. Thereafter, in a case where electron density of excitation level increases and the excitation level is satisfied, a Q value of the optical resonator increases and laser oscillation occurs by making the saturable absorber 18 transparent.

In the second embodiment, as an example, the saturable absorber 18 is disposed between the polarization control unit 16 and the reflection member 12B. The saturable absorber 18 is joined to the surface layer 17 at one end face substantially perpendicular to the optical axis of the optical resonator 12 and joined to the reflection member 12B at the other end face. Furthermore, the second surface 16b of the polarization control unit 16 is joined to one end face of the laser medium 11. The other end face of the laser medium 11 is joined to the reflection member 12A. Any of the joint surfaces has optical transparency, and the emission light 21 can be transmitted through the joint surface to appropriately generate laser oscillation. For joining these optical elements constituting the optical resonator 12, for example, plasma activated joining, atomic diffusion joining, surface activated joining, or the like is used.

In this manner, the surface layer 17 is provided in the grating structure GR of the polarization control unit 16. Thus, the first surface 16a of the polarization control unit 16 can be flattened, and the polarization control unit 16 and the saturable absorber 18 can be joined. That is, the first surface 16a of the polarization control unit 16 is joined to the saturable absorber (another optical element) 18 via the surface layer 17. The optical resonator 12 can be integrally formed by joining the pair of reflection members 12A and 12B and the optical elements provided therebetween. Thus, the size of the optical resonator 12 can be made compact. Furthermore, the length of the optical resonator 12 in the optical axis direction is shortened, the emission light 21 can be pulsed short, and the peak power of the emission light 21 can be increased. The configuration of the optical resonator 12 itself is simple and low cost is possible. The degree of freedom in designing the optical resonator 12 is also high, and a heat exhaust effect can also be obtained by disposing the optical resonator at a position adjacent to the laser medium 11.

Furthermore, in the second embodiment, the polarization control unit 16 is adjacent to and directly joined to the laser medium 11 on the second surface 16b opposite to the first surface 16a. Thus, the heat of the laser medium 11 can be exhausted via the polarization control unit 16. Note that another material (for example, a dielectric multilayer film) may be interposed between the polarization control unit 16 and the laser medium 11. In addition, a heat exhaust substrate (not illustrated) that exhausts heat of the laser medium 11 may be joined to the laser medium 11 separately from the polarization control unit 16.

Furthermore, the polarization characteristic of the grating structure GR is maintained, and for example, the transmittance of the TE polarized light beam can be suppressed while selectively maintaining high transmittance of the TM polarized light beam. That is, the polarization control unit 16 can maintain large anisotropy in the TM polarized light beam and the TE polarized light beam. As a result, stable polarization control can be performed in laser oscillation.

The other configurations of the second embodiment may be similar to the corresponding configurations of the first embodiment. Therefore, the second embodiment can obtain effects similar to those of the first embodiment.

### Modification

FIG. 4 is a schematic diagram illustrating a configuration example of an optical resonator 12 according to a modification of the second embodiment. In the optical resonator 12 according to the present modification, the pair of reflection members 12A and 12B and the optical elements provided therebetween are not joined but are separated from each other. In this case, the length of the optical resonator 12 becomes long and cannot be made compact, but the polarization characteristic of the polarization control unit 16 can be obtained as in the first embodiment. Note that, in the present modification, the surface layer 17 may not be provided. Note that the effects of the present embodiment are not lost even if the positions of the polarization control unit 16 and the saturable absorber 18 are replaced.

### Third Embodiment

FIG. 5 is a schematic diagram illustrating a configuration example of an optical resonator 12 according to a third embodiment. The third embodiment is different from the first embodiment in that the saturable absorber 18 is disposed between the laser medium 11 and the polarization control unit 16. As described above, even when the saturable absorber 18 is disposed at a different position between the pair of reflection members 12A and 12B, the emission light 21 reciprocating between the pair of reflection members 12A and 12B can be absorbed by the saturable absorber 18, so that the optical resonator 12 can function as passive Q-switching. Other configurations of the third embodiment may be similar to those of the second embodiment. Therefore, the third embodiment can obtain effects similar to those of the second embodiment. Furthermore, although not illustrated, in the third embodiment, each optical element may be separated as in the modification of the second embodiment.

### Fourth Embodiment

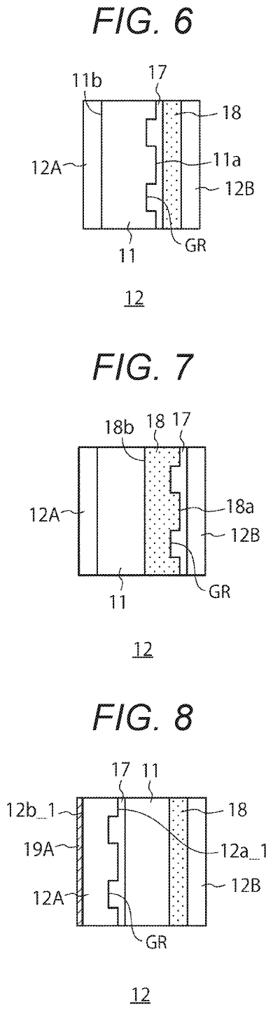

FIG. 6 is a schematic diagram illustrating a configuration example of an optical resonator 12 according to a fourth embodiment. According to the fourth embodiment, a grating structure GR is provided on a third surface 11a of the laser medium 11, and the laser medium 11 also has the function of the polarization control unit. Therefore, in the fourth embodiment, the polarization control unit 16 is omitted as a member. The surface layer 17 covers the grating structure GR on the third surface 11a. A fourth surface 11b of the laser medium 11 opposite to the third surface 11a is joined to the reflection member 12A.

As described above, even if the polarization control unit 16 is omitted, since the surface relief grating structure GR is provided on the third surface 11a of the laser medium 11, the emission light 21 from the laser medium 11 can be subjected to polarization control. Since the polarization control unit 16 is omitted, the length of the optical resonator 12 in the optical axis direction can be further shortened. Therefore, the emission light 21 can be further shortened in pulse length, and the peak power of the emission light 21 can be further increased.

Other configurations of the fourth embodiment may be similar to those of the second embodiment. Therefore, the fourth embodiment can obtain effects similar to those of the second embodiment. Furthermore, although not illustrated, in the fourth embodiment, each optical element may be separated as in the modification of the second embodiment.

### Fifth Embodiment

FIG. 7 is a schematic diagram illustrating a configuration example of an optical resonator 12 according to a fifth embodiment. According to the fifth embodiment, the grating structure GR is provided on a fifth surface 18a of the saturable absorber 18, and the saturable absorber 18 also has the function of the polarization control unit. Therefore, in the fifth embodiment, the polarization control unit 16 is omitted as a member. The surface layer 17 covers the grating structure GR on the fifth surface 18a. A sixth surface 18b of the laser medium 11 opposite to the fifth surface 18a is joined to the laser medium 11.

As described above, even if the polarization control unit 16 is omitted, since the surface relief grating structure GR is provided on the fifth surface 18a of the saturable absorber 18, the emission light 21 can be subjected to polarization control. Since the polarization control unit 16 is omitted, the length of the optical resonator 12 in the optical axis direction can be further shortened. Therefore, the emission light 21 can be further shortened in pulse length, and the peak power of the emission light 21 can be further increased.

Other configurations of the fifth embodiment may be similar to those of the fourth embodiment. Therefore, the fifth embodiment can obtain effects similar to those of the fourth embodiment. Furthermore, although not illustrated, in the fifth embodiment, each optical element may be separated as in the modification of the second embodiment.

### Sixth Embodiment

FIG. 8 is a schematic diagram illustrating a configuration example of an optical resonator 12 according to a sixth embodiment. According to the sixth embodiment, the grating structure GR is provided on a seventh surface 12a_1 of the reflection member (input coupler) 12A, and the reflection member 12A also has the function of the polarization control unit. Therefore, in the sixth embodiment, the polarization control unit 16 is omitted as a member. A reflection film 19A is provided on an eighth surface 12b_1 of the laser medium 11 on the opposite side of the seventh surface 12a_1. The surface layer 17 covers the grating structure GR on the seventh surface 12a_1. For the reflection film 12C, for example, a dielectric multilayer film can be used.

As described above, even if the polarization control unit 16 is omitted, since the surface relief grating structure GR is provided on the seventh surface 12a_1 of the reflection member 12A as an input coupler, the emission light 21 can be subjected to polarization control. Since the polarization control unit 16 is omitted, the length of the optical resonator 12 in the optical axis direction can be further shortened. Therefore, the emission light 21 can be further shortened in pulse length, and the peak power of the emission light 21 can be further increased.

Other configurations of the sixth embodiment may be similar to those of the fourth embodiment. Therefore, the sixth embodiment can obtain effects similar to those of the fourth embodiment. Furthermore, although not illustrated, in the sixth embodiment, each optical element may be separated as in the modification of the second embodiment.

### Seventh Embodiment

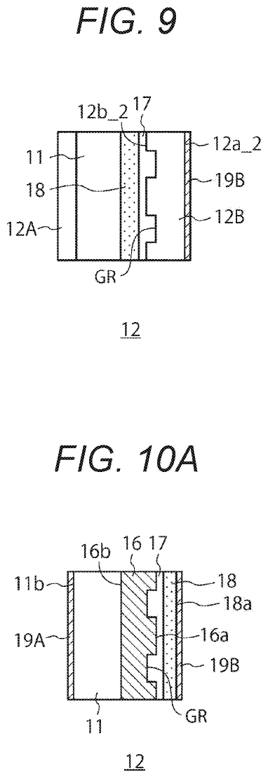

FIG. 9 is a schematic diagram illustrating a configuration example of an optical resonator 12 according to a seventh embodiment. According to the seventh embodiment, the grating structure GR is provided on a tenth surface 12b_2 of the reflection member (output coupler) 12B, and the reflection member 12B also has the function of the polarization control unit. Therefore, in the seventh embodiment, the polarization control unit 16 is omitted as a member. On an eleventh surface 12a_2 of the reflection member 12B opposite to the tenth surface 12b_2, a reflection film 19B is provided. The surface layer 17 covers the grating structure GR of the tenth surface 12b_2. For the reflection film 19B, for example, a dielectric multilayer film can be used.

As described above, even if the polarization control unit 16 is omitted, since the surface relief grating structure GR is provided on the tenth surface 12b_2 of the reflection member 12B as an output coupler, the emission light 21 can be subjected to polarization control. Since the polarization control unit 16 is omitted, the length of the optical resonator 12 in the optical axis direction can be further shortened. Therefore, the emission light 21 can be further shortened in pulse length, and the peak power of the emission light 21 can be further increased.

Other configurations of the seventh embodiment may be similar to those of the fourth embodiment. Therefore, the seventh embodiment can obtain effects similar to those of the fourth embodiment. Furthermore, although not illustrated, in the seventh embodiment, each optical element may be separated as in the modification of the second embodiment.

### Eighth Embodiment

FIGS. 10A and 10B are schematic diagrams illustrating a configuration example of an optical resonator 12 according to an eighth embodiment. According to the eighth embodiment, a pair of reflection films 19A and 19B is provided instead of the pair of reflection members 12A and 12B. The reflection film 19A is provided on the fourth surface 11b of the laser medium 11. The reflection film 19B is provided on the fifth surface 18a of the saturable absorber 18. The reflection film 19A has both a function of a mirror that reflects the emission light 21 and a function of an input coupler. The reflection film 19B has both a function of a mirror that reflects the emission light 21 and a function of an output coupler. For the reflection films 19A and 19B, for example, a dielectric multilayer film can be used.

In the eighth embodiment, the polarization control unit 16 is provided, and the grating structure GR is provided on the first surface 16a of the polarization control unit 16.

As described above, the reflection films 19A and 19B may be provided as an input coupler and an output coupler. Other configurations of the eighth embodiment may be similar to those of the second embodiment. Therefore, the eighth embodiment can obtain effects similar to those of the second embodiment. Furthermore, although not illustrated, in the eighth embodiment, each optical element may be separated as in the modification of the second embodiment. Furthermore, the eighth embodiment may be combined with other embodiments.

As illustrated in FIG. 10B, the transparent member HE may be added to the optical resonator 12. The transparent member HE is disposed on the optical axis. In FIG. 10B, the transparent member HE is adjacent to the laser medium 11 via the reflection film 19A, and has a function of exhausting heat of the laser medium 11. As the transparent member HE, a material transparent to the excitation light, for example, sapphire (Al₂O₃) is used.

The transparent member HE is preferably in direct contact with the laser medium 11 in consideration of a heat exhaust effect. However, the transparent member HE may be disposed at any position between the reflection films 19A and 19B. The transparent member HE functions as a spacer, and can increase the excitation efficiency of the emission light by adjusting the resonator length of the optical resonator 12. Furthermore, in a case of being adjacent to the laser medium 11, the transparent member HE also has an effect of exhausting heat of the laser medium 11. In this case, as the transparent member HE, a material transparent to the emission light or the excitation light, for example, sapphire (Al₂O₃) is used.

### Ninth Embodiment

FIG. 11 is a schematic diagram illustrating a configuration example of a polarization control unit 16 according to a ninth embodiment. According to the ninth embodiment, a protrusion 16c of the grating structure GR of the polarization control unit 16 is formed by a material different from that of the other polarization control unit 16. For example, a dielectric (for example, Al₂O₃, SiO₂, Ta₂O₅, or HfO₂), a semiconductor (for example, GaN, InN, or AlN), or the like is used for the polarization control unit 16 and the protrusion 16c. The protrusion 16c is formed by a material different from that of the polarization control unit 16, and thus the refractive indexes are different from each other. As described above, the protrusion 16c of the grating structure GR may be different from the other polarization control units 16 in the refractive index. The polarization control of the emission light 21 may be performed by changing the material of the protrusion 16c of the grating structure GR in the polarization control unit 16.

The material of the protrusion 16c is deposited on the first surface 16a of the grating structure GR, and then the material of the protrusion 16c is processed using a lithography technique and an etching technique. Thus, the protrusion 16c is formed on the first surface 16a. The polarization control unit 16 according to the ninth embodiment may be applied to any of the above-described embodiments including the polarization control unit 16.

### Tenth Embodiment

FIG. 12 is a schematic diagram illustrating a configuration example of a laser device 10 according to a tenth embodiment. According to the tenth embodiment, the light source 13 is joined to the reflection member 12A (input coupler) of the optical resonator 12. The light source 13 is formed integrally with the optical resonator 12. The light source 13 generates excitation light and irradiates the laser medium 11 with the excitation light. The optical resonator 12 may be any of the embodiments of the present description. By integrating the light source 13 and the optical resonator 12, the size of the entire laser device 10 becomes compact. Furthermore, since the excitation light from the light source 13 is directly incident on the optical resonator 12, the emission light 21 can be efficiently generated.

### Eleventh Embodiment

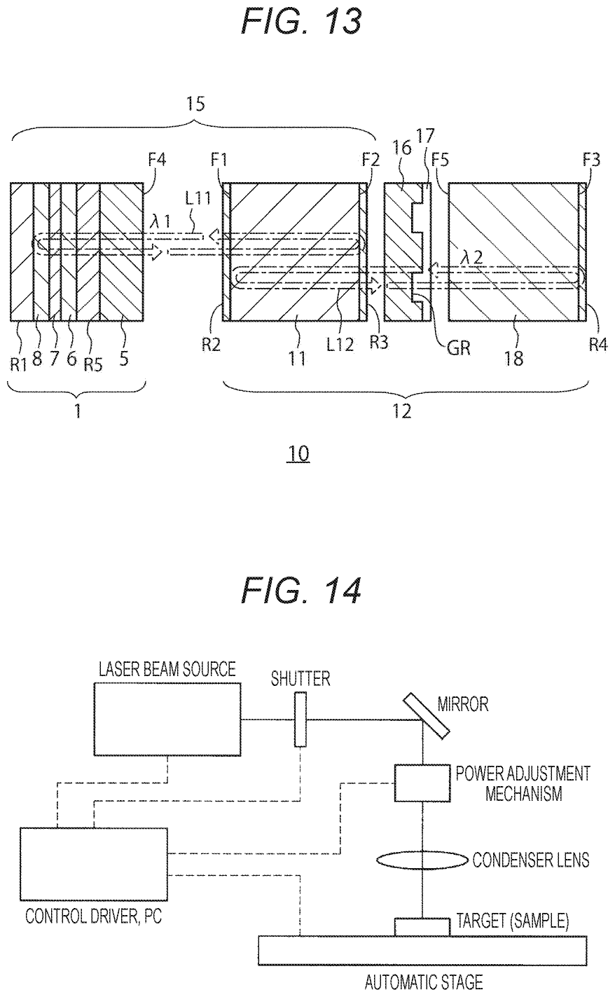

FIG. 13 is a diagram illustrating a configuration example of a laser device 10 according to an eleventh embodiment. The laser device 10 is a laser device in which the light emitting element 1, the solid-state laser medium 11, and the saturable absorber 18 are integrally joined.

The light emitting element 1 is a surface emitting element and has semiconductor layers of a stacked structure. The light emitting element 1 has a structure in which a substrate 5, a fifth reflection layer R5, a cladding layer 6, an active layer 7, a cladding layer 8, and a first reflection layer R1 are stacked in this order. Note that the light emitting element 1 in FIG. 13 has a bottom emission type configuration in which continuous wave (CW) excitation light is emitted from the substrate 5, but may have a top emission type configuration in which the CW excitation light is emitted from the first reflection layer R1 side.

The substrate 5 is, for example, an n-GaAs substrate. Since the n-GaAs substrate 5 absorbs light having a first wavelength λ1, which is the excitation wavelength of the light emitting element 1, at a certain rate, this is desirably made as thin as possible. In contrast, it is desirable to provide such a thickness that can maintain mechanical strength at the time of a joining process to be described later.

The active layer 7 performs surface emission at the first wavelength λ1. The cladding layers 6 and 8 are, for example, AlGaAs cladding layers. The first reflection layer R1 reflects the light having the first wavelength λ1. The fifth reflection layer R5 has a certain transmittance with respect to the light having the first wavelength λ1. For the first reflection layer R1 and the fifth reflection layer R5, for example, a semiconductor distributed Bragg reflector (DBR) capable of performing electrical conduction is used. A current is externally injected via the first reflection layer R1 and the fifth reflection layer R5, recombination and light emission occur in a quantum well in the active layer 7, and light emission at the first wavelength λ1 is performed.

The fifth reflection layer R5 is arranged on, for example, the n-GaAs substrate 5. For example, the fifth reflection layer R5 includes a multilayer reflection film containing Al_{z1}Ga_{1-z1}As/Al_{z2}Ga_{1-z2}As (0≤ z1≤ z2≤1) to which an n-type dopant (for example, silicon) is added. The fifth reflection layer R5 is also referred to as n-DBR.

The active layer 7 includes, for example, a multiple quantum well layer in which an Alₓ₁In_{y1}Ga_{1-x1-y1}As layer and an Alₓ₃In_{y3}Ga_{1-x3-y3}As layer are stacked.

The first reflection layer R1 includes, for example, a multilayer reflection film containing Al_{z3}Ga_{1-z3}As/Al_{z4}Ga_{1-z4}As (0≤z3≤z4≤1) to which a p-type dopant (for example, carbon) is added. The first reflection layer R1 is also referred to as p-DBR.

Each of the semiconductor layers R5, 6, 7, 8, and R1 in the light source 13 as an excitation light resonator can be formed by using a crystal growth method such as a metal organic chemical vapor deposition (MOCVD) method or a molecular beam epitaxy (MBE) method. Then, after the crystal growth, driving by current injection becomes possible after processes such as mesa etching for element separation, formation of an insulating film, and vapor deposition of an electrode film.

The solid-state laser medium 11 is joined to an end face opposite to the fifth reflection layer R5 of the n-GaAs substrate 5 of the light emitting element 1. Hereinafter, an end face on the light emitting element 1 side of the solid-state laser medium 11 is referred to as a twelfth surface F1, and an end face on the saturable absorber 18 side of the solid-state laser medium 11 is referred to as a thirteenth surface F2. Furthermore, a laser pulse emission surface of the saturable absorber 18 is referred to as a fourteenth surface F3, and an end face on the solid-state laser medium 11 side of the light emitting element 1 is referred to as a fifteenth surface F4. Furthermore, an end face on the solid-state laser medium 11 side of the saturable absorber 18 is referred to as a sixteenth surface F5. Although illustrated separately for convenience in FIG. 1, the fifteenth surface F4 of the light emitting element 1 is joined to the twelfth surface F1 of the solid-state laser medium 11, and the thirteenth surface F2 of the solid-state laser medium 11 is joined to the sixteenth surface F5 of the saturable absorber 18.

The laser device 10 includes a first resonator 15 and a second resonator 12. The first resonator 15 causes excitation light L11 having the first wavelength λ1 to resonate between the first reflection layer R1 in the light emitting element 1 and a third reflection layer R3 in the solid-state laser medium 11. The second resonator 12 causes emission light L12 having the second wavelength λ2 to resonate between a second reflection layer R2 in the solid-state laser medium 11 and a fourth reflection layer R4 in the saturable absorber 18.

The second resonator 12 constitutes a configuration of what is called a Q-switched solid-state laser resonator. The third reflection layer R3, which is a high reflection layer, is provided in the solid-state laser medium 11 so that the first resonator 15 can perform a stable resonance operation. In a case of a normal resonator, the third reflection layer R3 in FIG. 13 has a function of an output coupler and is a partial reflection for emitting light having the first wavelength λ1 to the outside. In contrast, in the first resonator 15 in FIG. 13, the high reflection layer is used as the third reflection layer R3 in order to confine, by the third reflection layer R3, power of the excitation light L11 having the first wavelength λ1 in the first resonator 15.

In this manner, three reflection layers (first reflection layer R1, fifth reflection layer R5, and third reflection layer R3) are provided inside the first resonator 15 including the light emitting element 1 and the solid-state laser medium 11. Therefore, the first resonator 15 has a coupled resonator (coupled cavity) structure.

The solid-state laser medium 11 is excited by confining the power of the excitation light L11 having the first wavelength λ1 in the first resonator 15. Thus, Q-switched laser pulse oscillation occurs in the second resonator 12. The second resonator 12 causes the light having the second wavelength λ2 to resonate between the second reflection layer R2 in the solid-state laser medium 11 and the fourth reflection layer R4 in the saturable absorber 18. The second reflection layer R2 is a high reflection layer, whereas the fourth reflection layer R4 is a partial reflection layer having a function of an output coupler. In FIG. 13, the fourth reflection layer R4 is provided on an end face of the saturable absorber 18.

Here, one of the polarization control units 16 according to the above embodiments is provided between the laser medium 11 and the saturable absorber 18. The polarization control unit 16 has a planar relief grating structure GR in the optical path of the emission light L12. Thus, the effect of any one of the above embodiments can be obtained also in the laser device 10. The grating structure GR of the polarization control unit 16 is covered and planarized by the surface layer 17.

The solid-state laser medium 11 contains, for example, ytterbium (Yb)-doped yttrium aluminum garnet (YAG) crystal Yb:YAG. In this case, the first wavelength λ1 of the first resonator 15 is 940 nm, and the second wavelength λ2 of the second resonator 12 is 1030 nm.

The solid-state laser medium 11 is not limited to Yb:YAG, and for example, at least any material of Nd:YAG, Nd:YVO4, Nd:YLF, Nd:glass, Yb:YAG, Yb:YLF, Yb:FAP, Yb:SFAP, Yb:YVO, Yb:glass, Yb:KYW, Yb:BCBF, Yb:YCOB, Yb:GdCOB, and Yb:YAB can be used as the solid-state laser medium 11. Note that a form of the solid-state laser medium 11 is not limited to a crystal, and the use of a ceramic material is not prevented.

Furthermore, the solid-state laser medium 11 may be a four-level system solid-state laser medium 11 or a three-level system solid-state laser medium 11. However, since an appropriate excitation wavelength (first wavelength λ1) varies depending on each crystal, it is necessary to select the semiconductor material of the light emitting element 1 according to the material of the solid-state laser medium 11.

The saturable absorber 18 contains, for example, a chromium (Cr)-doped YAG (Cr:YAG) crystal. The saturable absorber 18 is a material of which transmittance increases when intensity of incident light exceeds a predetermined threshold. The excitation light L11 having the first wavelength λ1 by the first resonator 15 increases the transmittance of the saturable absorber 18 to emit the laser pulse having the second wavelength λ2. This is referred to as Q-switching. As a material of the saturable absorber 18, V:YAG can also be used. However, other types of saturable absorber 18 may also be used. Furthermore, the use of an active Q-switched element as the Q-switching is not prevented.

In FIG. 13, the light emitting element 1, the solid-state laser medium 11, the polarization control unit 16, and the saturable absorber 18 are separately illustrated, but they are joined to be integrated by using a joining process to form a stacked structure. Examples of the joining process include room-temperature joining, atomic diffusion bonding, plasma activation joining and the like. Alternatively, other joining (adhering) processes can be used.

In order to stably join the solid-state laser medium 11 to the light emitting element 1, it is necessary to flatten the surface of the n-GaAs substrate 5 in the light emitting element 1. Therefore, as described above, it is desirable that electrodes for injecting a current into the first reflection layer R1 and the fifth reflection layer R5 be arranged so as not to be exposed at least on the surface of the n-GaAs substrate 5.

In this manner, by forming the laser device 10 into a stacked structure, it becomes easy to form a plurality of chips by dicing the stacked structure to separate after fabricating the same, or to form a laser array in which a plurality of laser devices 10 is arranged in an array on one substrate.

In a case where the laser device 10 having a stacked structure is manufactured by a joining process, the surface roughness Ra of each layer needs to be equal to or less than about 1 nm. Furthermore, in order to avoid an optical loss at an interface of each layer, a dielectric multilayer film may be arranged between the layers, and the layers may be joined via the dielectric multilayer film. For example, the n-GaAs substrate 5 as a base substrate of the light emitting element 1 has a refractive index n of 3.2, which is higher than that of YAG (n:1.8) or a general dielectric multilayer film material. Therefore, when the solid-state laser medium 11 and the saturable absorber 18 are joined to the light emitting element 1, it is necessary to prevent the optical loss due to refractive index mismatch from occurring. Specifically, it is desirable to arrange an anti-reflection film (AR coating film or non-reflection coating film) that does not reflect the light having the first wavelength λ1 of the first resonator 15 between the light emitting element 1 and the solid-state laser medium 11. Furthermore, it is desirable to arrange an anti-reflection film (AR coating film or non-reflection coating film) also between the solid-state laser medium 11 and the saturable absorber 18.

Polishing is sometimes difficult depending on a joining material, and for example, it is possible to deposit a material transparent with respect to the first wavelength λ1 and the second wavelength λ2 such as SiO₂ as a base layer for joining, and polish this SiO₂ layer to have surface roughness Ra of about 1 nm to use as an interface for joining. Here, a material other than SiO₂ can be used as the base layer, and the material is not limited.

Examples of the dielectric multilayer film include a short wave pass filter (SWPF), a long wave pass filter (LWPF), a band pass filter (BPF), an anti-reflection (AR) protective film and the like. It is desirable to arrange different types of dielectric multilayer films as necessary. A physical vapor deposition (PVD) method can be used as a film deposition method of the dielectric multilayer film, and specifically, the film deposition method such as vacuum vapor deposition, ion-assisted vapor deposition, and sputtering can be used. It does not matter which film deposition method is applied. Furthermore, any characteristic of the dielectric multilayer film can be selected, and for example, the second reflection layer R2 may be the short wave pass filter, and the third reflection layer R3 may be the long wave pass filter.

According to the eleventh embodiment, the polarization control unit 16 that controls the ratio of the TM polarized light beam and the TE polarized light beam orthogonal to each other is provided inside the second resonator 12. Alternatively, the planar relief grating structure GR may be formed on the surface of the laser medium 11 as illustrated in FIG. 6. As illustrated in FIG. 7, the planar relief grating structure GR may be formed on the surface of the saturable absorber 18. The planar relief grating structure GR may be formed in the reflection layer R2 or R3 as illustrated in FIG. 8 or FIG. 9. In this manner, the planar relief grating structure GR may be provided as a diffraction grating inside the second resonator 12 to control the polarization state of the emission light L12.

### (Operation of Laser Device 10 in FIG. 13)

Next, an operation of the laser device 10 in FIG. 13 will be described. By injecting a current into the active layer 7 via the electrode of the light emitting element 1, laser oscillation at the first wavelength λ1 occurs in the first resonator 15, and the excitation light L11 is generated. When the excitation light L11 is incident on the solid-state laser medium 11, the solid-state laser medium 11 is excited, and the emission light L12 having the second wavelength λ2 is generated. Since the saturable absorber 18 is joined to the solid-state laser medium 11 and the polarization control unit 16, in an initial stage when the laser oscillation occurs at the first resonator 15, the emission light L12 from the solid-state laser medium 11 is absorbed by the saturable absorber 18, so that light emission by the fourth reflection layer R4 on the emission surface side of the saturable absorber 18 does not occur, and the Q-switched laser oscillation does not occur.

Thereafter, when the solid-state laser medium 11 is put into a sufficiently excited state, and an output of the emission light L12 is increased to exceed a certain threshold, a light absorption rate in the saturable absorber 18 rapidly decreases, and the spontaneous emission light L12 generated in the solid-state laser medium 11 can be transmitted through the saturable absorber 18. Thus, the second resonator 12 causes the emission light L12 to resonate between the reflection layer R2 and the reflection layer R4, and laser beam is output from the reflection layer R4 side. When the emission light L12 is resonated in the second resonator 12, the emission light passes through the grating structure GR, whereby polarization control is performed as in the above embodiment. When Q-switched laser oscillation occurs in the second resonator 12, the emission light L12 subjected to polarization control is emitted as laser beam from the fourth reflection layer R4 toward the space on the right side in FIG. 13. Thus, the laser beam is output as a Q-switched laser pulse. As described above, the above embodiment may be applied to the laser device of FIG. 13.

Note that a non-linear optical crystal for wavelength conversion can be arranged inside the second resonator 12. The wavelength of the laser pulse after the wavelength conversion can be changed depending on a type of the non-linear optical crystal. Examples of wavelength converting materials include non-linear optical crystals such as LiNbO₃, BBO, LBO, CLBO, BiBO, KTP, and SLT. Furthermore, a phase-matching material similar to them may be used as the wavelength converting material. Note that the type of the wavelength converting material is not limited. The second wavelength λ2 can be converted to another wavelength by the wavelength converting material.

### Example of Polarization Control Unit 16

As an example of the polarization control unit 16, a photonic crystal polarizing element using a photonic crystal or a polarizing element using a meta-surface may be used. That is, the microstructure of the polarization control unit 16 may be a photonic crystal structure or a meta-surface structure in addition to the grating structure.

Note that, in a case where the output of the laser beam emitted from the passive Q-switched pulsed laser device 10 according to the present embodiment is high, the electric field amplitude inside the optical resonator 12 is large. That is, since the load applied to the polarization control unit 16 increases, it is more preferable to use a polarizing element that can withstand the required output. In this respect, the photonic crystal can exhibit higher resistance to a load caused by laser oscillation depending on a material, a structure, or the like.

Note that, in order to more efficiently perform laser oscillation with respect to the emission light 21 in a desired polarization direction, a difference in reflectance of the photonic crystal polarizing element with respect to the emission light 21 in polarization directions (TM and TE) orthogonal to each other is preferably 1% or more. However, without being limited thereto, the difference in reflectance of the photonic crystal polarizing element with respect to the emission light 21 in the polarization directions orthogonal to each other may be appropriately changed.

In addition, in order to more efficiently perform laser oscillation and improve resistance, the thickness per layer of the photonic crystal constituting the photonic crystal polarizing element is preferably substantially the same as the wavelength of the emission light 21. However, without being limited thereto, the thickness per layer of the photonic crystal may be appropriately changed. For example, the thickness per layer of photonic crystal may be thinner (or thicker) by a predetermined value than the wavelength of the emission light 21.

In addition, in order to more efficiently perform laser oscillation and improve resistance, the number of stacked photonic crystals is preferably about several cycles to several hundred periods. However, without being limited thereto, the number of stacked photonic crystals may be appropriately changed.

Furthermore, as the material of the photonic crystal, for example, SiO₂, SiN, Ta₂O₅, or the like can be used. However, without being limited thereto, and the material of the photonic crystal may be appropriately changed.

Note that such a photonic crystal can be formed by alternately stacking SiO₂, Nb₂O₅, Ta₂O₅, Al₂O₃, or the like on a substrate having a periodic structure in advance by vapor deposition or sputtering.

The meta-surface structure is a nano-sized fine structure equal to or less than the light wavelength formed on the surface of the substrate, and may be, for example, a nano-pillar array structure separated at an interval equal to or less than the light wavelength. Such a meta-surface structure has a function of operating a phase, an amplitude, polarization, and the like of light. Such a meta-surface structure may be provided on the surface of the polarization control unit 16.

### Examples of Laser Medium 11 and Saturable Absorber 18

In the above embodiment, Yb:YAG is used as the laser medium 11, and Cr:YAG is used as the saturable absorber 18. However, this is merely an example, and the combination of the laser medium 11 and the saturable absorber 18 can be appropriately changed.

As a modification of the present disclosure, a combination of the laser medium 11 and the saturable absorber 18 applicable to the passive Q-switched pulsed laser device 10 will be described.

The solid-state laser medium 11 contains, for example, ytterbium (Yb)-doped yttrium aluminum garnet (YAG) crystal Yb:YAG. In this case, the first wavelength λ1 of the first resonator 15 is 940 nm, and the second wavelength λ2 of the second resonator 12 is 1030 nm.

The solid-state laser medium 11 is not limited to Yb:YAG, and for example, at least any material of Nd:YAG, Nd:YVO4, Nd:YLF, Nd:glass, Yb:YAG, Yb:YLF, Yb:FAP, Yb:SFAP, Yb:YVO, Yb:glass, Yb:KYW, Yb:BCBF, Yb:YCOB, Yb:GdCOB, and Yb:YAB can be used as the solid-state laser medium 11. Note that a form of the solid-state laser medium 11 is not limited to a crystal, and the use of a ceramic material is not prevented.

Furthermore, the solid-state laser medium 11 may be a four-level system solid-state laser medium 11 or a three-level system solid-state laser medium 11. However, since an appropriate excitation wavelength (first wavelength λ1) varies depending on each crystal, it is necessary to select the semiconductor material of the light emitting element 1 according to the material of the solid-state laser medium 11.

The passive Q-switched pulsed laser device 10 according to the present embodiment can be applied to various devices, systems, and the like. For example, the passive Q-switched pulsed laser device 10 according to the present embodiment may be applied to a device used for processing a metal, a semiconductor, a dielectric, a resin, a living body, or the like, a device used for Light Detection and Ranging Laser Imaging Detection and Ranging (LIDAR), a device used for laser induced breakdown spectroscopy (LIBS), a device used for refractive correction eye surgery (for example, LASIK or the like), a device used for LIDAR for atmospheric observation such as depth sensing or aerosol, or the like. Note that the apparatus to which the passive Q-switched pulsed laser device 10 according to the present embodiment is applied is not limited to the above.

FIG. 14 is a block diagram illustrating an application example in which the laser device 10 according to the present embodiment is applied to a laser processing device. In a case where the passive Q-switched pulsed laser device 10 according to the present embodiment is applied to a processing device or a medical device, for example, as illustrated in FIG. 14, a configuration can be employed in which the passive Q-switched pulsed laser device 10 of the present embodiment is used as a laser beam source, a shutter, a mirror, and a power adjustment mechanism are controlled by a control driver, and a target on an automatic stage is irradiated with light by a condenser lens.

Note that the present technology can also employ the following configurations.

(1)

An optical resonator, including:
a pair of reflection members;
a laser medium that is disposed between the pair of reflection members and is excited by specific excitation light to emit emission light; and
a polarization control unit that is disposed between the pair of reflection members and controls polarization of the emission light, in which
the polarization control unit has a microstructure on a surface so as to have different transmittances for polarized light beams orthogonal to each other out of zeroth-order diffracted light of the emission light.

(2)

The optical resonator according to (1), in which the microstructure is a grating structure.

(3)

The optical resonator according to (1) or (2), in which the microstructure is an uneven structure having a period equal to or less than a wavelength of the emission light.

(4)

The optical resonator according to (2) or (3), in which the microstructure is an uneven structure having a depth equal to or less than ¼ of a wavelength of the emission light.

(5)

The optical resonator according to any one of (1) to (4), further including a surface layer provided on a surface of the microstructure.

(6)

The optical resonator according to any one of (1) to (5), in which in the polarization control unit, a transparent material is used for the emission light.

(7)

The optical resonator according to any one of (1) to (6), in which the polarization control unit is joined to the laser medium and constitutes an integrated optical resonator.

(8)

The optical resonator according to any one of (1) to (7), in which the pair of reflection members, the polarization control unit, and the laser medium constitute an integrated optical resonator.

(9)

The optical resonator according to any one of (1) to (8), further including a saturable absorber disposed on an optical axis of the optical resonator between the pair of reflection members.

(10)

The optical resonator according to any one of (1) to (9), further including a transparent member including a material transparent to emission light or excitation light, the transparent member being disposed on an optical axis of the optical resonator between the pair of reflection members or outside the reflection member on an incident side of the excitation light.

(11)

The optical resonator according to (4), in which
any one of a dielectric (for example, Al₂O₃, SiO₂, Ta₂O₅, or HfO₂) and a semiconductor (for example, GaN, InN, or AlN) is used for the polarization control unit, and
quartz (SiO₂) is used for the surface layer.

(12)

The optical resonator according to any one of (1) and (5) to (10), in which the microstructure is a photonic crystal or a meta-surface structure.

(13)

An optical resonator, including:
a pair of reflection members;
a laser medium that is disposed between the pair of reflection members and is excited by specific excitation light to emit emission light; and
a saturable absorber disposed on an optical axis of the optical resonator between the pair of reflection members, in which
any one of the saturable absorber, the laser medium, or the reflection member has a microstructure on a surface so as to have different transmittances for polarized light beams orthogonal to each other out of zeroth-order diffracted light of the emission light.

(14)

The optical resonator according to (13), in which the microstructure is a grating structure.

(15)

The optical resonator according to (14), in which the microstructure is an uneven structure having a period equal to or less than a wavelength of the emission light.

(16)

The optical resonator according to (14) or (15), in which the microstructure is an uneven structure having a depth equal to or less than ¼ of a wavelength of the emission light.

(17)

The optical resonator according to any one of (13) to (16), further including a surface layer provided on a surface of the microstructure.

(18)

The optical resonator according to any one of (13) to (17), in which the pair of reflection members, the polarization control unit, and the laser medium constitute an integrated optical resonator.

(19)

The optical resonator according to any one of (13) to (18), further including a transparent member including a material transparent to emission light or excitation light, the transparent member being disposed on an optical axis of the optical resonator between the pair of reflection members or outside the reflection member on an incident side of the excitation light.

(20)

The optical resonator according to any one of (13) and (17) to (19), in which the microstructure is a photonic crystal or a meta-surface structure.

(21)

A laser device, including:
the optical resonator according to any one of (1) to (20); and
a light source that irradiates the laser medium with the excitation light.

(22)

The laser device according to (21), in which the optical resonator and the light source are integrally formed.

(23)

A laser device, including:
the optical resonator according to any one of (1) to (20); and
an excitation light resonator that oscillates the excitation light.

Note that the present disclosure is not limited to the above-described embodiments, and various modifications can be made without departing from the gist of the present disclosure. Furthermore, the effects described in the present description are merely examples and are not limited, and other effects may be provided.

### REFERENCE SIGNS LIST

10 Laser device
11 Laser medium
12 Optical resonator
12A, 12B Reflection member
13 Light source
16 Polarization control unit
GR Grating structure
17 Surface layer
18 Saturable absorber

1. An optical resonator, comprising:
a pair of reflection members;
a laser medium that is disposed between the pair of reflection members and is excited by specific excitation light to emit emission light; and
a polarization control unit that is disposed between the pair of reflection members and controls polarization of the emission light, wherein
the polarization control unit has a microstructure on a surface so as to have different transmittances for polarized light beams orthogonal to each other out of zeroth-order diffracted light of the emission light.

2. The optical resonator according to claim 1, wherein the microstructure is a grating structure.

3. The optical resonator according to claim 2, wherein the microstructure is an uneven structure having a period equal to or less than a wavelength of the emission light.

4. The optical resonator according to claim 2, wherein the microstructure is an uneven structure having a depth equal to or less than ¼ of a wavelength of the emission light.

5. The optical resonator according to claim 1, further comprising a surface layer provided on a surface of the microstructure.

6. The optical resonator according to claim 1, wherein in the polarization control unit, a transparent material is used for the emission light.

7. The optical resonator according to claim 1, wherein the polarization control unit is joined to the laser medium and constitutes an integrated optical resonator.

8. The optical resonator according to claim 1, wherein the pair of reflection members, the polarization control unit, and the laser medium constitute an integrated optical resonator by joining.

9. The optical resonator according to claim 1, further comprising a saturable absorber disposed on an optical axis of the optical resonator between the pair of reflection members.

10. The optical resonator according to claim 1, further comprising a transparent member including a material transparent to emission light or excitation light, the transparent member being disposed on an optical axis of the optical resonator between the pair of reflection members or outside the reflection member on an incident side of the excitation light.

11. The optical resonator according to claim 5, wherein
any one of a dielectric (for example, Al₂O₃, SiO₂, Ta₂O₅, or HfO₂) and a semiconductor (for example, GaN, InN, or AlN) is used for the polarization control unit, and
quartz (SiO₂) is used for the surface layer.

12. The optical resonator according to claim 1, wherein the microstructure is a photonic crystal or a meta-surface structure.

13. An optical resonator, comprising:
a pair of reflection members;
a laser medium that is disposed between the pair of reflection members and is excited by specific excitation light to emit emission light; and
a saturable absorber disposed on an optical axis of the optical resonator between the pair of reflection members, wherein
any one of the saturable absorber, the laser medium, or the reflection member has a microstructure on a surface so as to have different transmittances for polarized light beams orthogonal to each other out of zeroth-order diffracted light of the emission light.

14. The optical resonator according to claim 13, wherein the microstructure is a grating structure.

15. The optical resonator according to claim 14, wherein the microstructure is an uneven structure having a period equal to or less than a wavelength of the emission light.

16. The optical resonator according to claim 14, wherein the microstructure is an uneven structure having a depth equal to or less than ¼ of a wavelength of the emission light.

17. The optical resonator according to claim 13, further comprising a surface layer provided on a surface of the microstructure.

18. The optical resonator according to claim 13, wherein the pair of reflection members, the polarization control unit, and the laser medium constitute an integrated optical resonator by joining.

19. The optical resonator according to claim 13, further comprising a transparent member including a material transparent to emission light or excitation light, the transparent member being disposed on an optical axis of the optical resonator between the pair of reflection members or outside the reflection member on an incident side of the excitation light.

20. The optical resonator according to claim 13, wherein the microstructure is a photonic crystal or a meta-surface structure.

21. A laser device, comprising:
the optical resonator according to claim 1; and
a light source that irradiates the laser medium with the excitation light.

22. The laser device according to claim 21, wherein the optical resonator and the light source are integrally formed.

23. A laser device, comprising:
an optical resonator according to claim 1; and
an excitation light resonator that oscillates the excitation light.
